(19) United States
(12) Patent Application Publication
(10) Pub. No.: US 2026/0190703 A1
(43) Pub. Date: Jul. 2, 2026

(54) DISPLAY DEVICE

(71) Applicant: LG Display Co., Ltd., Seoul (KR)

(72) Inventors: Jae-Hwan MYUNG, Paju-si (KR); Hoon-Sok SON, Paju-si (KR); Min-Ki KIM, Paju-si (KR)

(73) Assignee: LG Display Co., Ltd., Seoul (KR)

(21) Appl. No.: 19/369,295

(22) Filed: Oct. 26, 2025

(30) Foreign Application Priority Data
Dec. 26, 2024 (KR) 10-2024-0196876

(51) Int. Cl. H10K 59/131

(52) U.S. Cl. CPC H10K 59/131

(57) ABSTRACT

A display device includes: a display panel including plurality of pad electrodes arranged on a pad region of a substrate; and a panel driving circuit attached to the pad region through an anisotropic conductive film containing conductive balls and including bumps respectively connected to the plurality of pad electrodes through the conductive balls. A pad groove defined by at least a portion of a pad electrode, among the plurality of pad electrodes, may be formed in a unit region where the pad electrode is disposed.

### CROSS REFERENCE TO RELATED APPLICATION

The present application claims the priority benefit of Korean Patent Application No. 10-2024-0196876, filed in the Republic of Korea on Dec. 26, 2024, which is hereby incorporated by reference in its entirety for all purposes as if fully set forth herein.

### BACKGROUND

### Field of the Disclosure

The present disclosure relates to a display device.

### Discussion of the Related Art

Recently, flat panel display devices with excellent characteristics, such as thinness, weight reduction, and low power consumption, have been widely developed and applied to various fields.

Among the flat panel display devices, light emitting display devices equipped with light emitting elements, such as light emitting diodes, are display devices that emit light when charges are injected into a light emitting layer formed between an anode and a cathode, and electrons and holes are paired and then extinguished.

Recently, a resolution of the light emitting display device has increased, resulting in an increase in a number of pad electrodes. Thus, it is necessary to reduce a pitch of the pad electrodes. However, a region where the pad electrodes are placed is limited, and the pad electrodes require a contact surface larger than a certain size, making it considerably difficult to reduce the pitch of the pad electrodes.

### SUMMARY

An advantage of the present disclosure is to provide a display device that can reduce a pitch of pad electrodes.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a display panel including a plurality of pad electrodes arranged on a pad region of a substrate; and a panel driving circuit attached to the pad region through an anisotropic conductive film containing conductive balls and including bumps respectively connected to the plurality of pad electrodes through the conductive balls, wherein a pad groove defined by at least a portion of a pad electrode, among the plurality of pad electrodes, is formed in a unit region where the pad electrode is disposed. In addition, in another aspect, a display device includes: a display panel including a display region and a non-display region arranged around the display region; and a driving circuit portion for driving the display panel, wherein the non-display region includes a pad region, and a plurality of pad electrodes is arranged on a substrate in the pad region, and wherein a pad groove is formed in at least one of the plurality of pad electrodes.

It is to be understood that both the foregoing general description and the following detailed description are by way of example and explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this specification, illustrate example embodiments of the disclosure and together with the description serve to explain various principles of the disclosure. In the drawings:

FIG. 1 is a plan view schematically illustrating a configuration of a display device according to a first example embodiment of the present disclosure;

FIG. 2 is a side view schematically illustrating attachment of a display panel and a panel driving circuit in a display device according to a first example embodiment of the present disclosure;

FIG. 3 is a circuit view schematically illustrating an example of a structure of a subpixel according to a first example embodiment of the present disclosure;

FIGS. 4A, 4B, 5, and 6 are cross-sectional views illustrating various examples of a structure of a pad groove formed in a pad electrode according to a first example embodiment of the present disclosure;

FIGS. 7 to 9 are cross-sectional views illustrating various examples of a structure of a pad groove formed in a pad electrode of a display device according to a second example embodiment of the present disclosure;

FIGS. 10 and 11 are cross-sectional views illustrating various examples of a structure of a pad groove formed in a pad electrode of a display device according to a third example embodiment of the present disclosure;

FIGS. 12 and 13 are cross-sectional views illustrating various examples of a structure of a pad groove formed in a pad electrode of a display device according to a fourth example embodiment of the present disclosure; and

FIG. 14 is a cross-sectional view illustrating an example of a structure of a pad groove formed in a pad electrode of a display device according to a fifth example embodiment of the present disclosure.

### DETAILED DESCRIPTION

Advantages and features of the present disclosure and methods of achieving them will be apparent with reference to the example embodiments described below in detail with the accompanying drawings. However, the present disclosure is not limited to the example embodiments disclosed below, but can be realized in a variety of different forms. The present disclosure is provided to fully inform the scope of the disclosure to those skilled in the art of the present disclosure, and the protective scope of the present disclosure may be defined by the scope of the claims and their equivalents.

The shapes, sizes, proportions, angles, numbers, and the like disclosed in the drawings for explaining the embodiments of the present disclosure are illustrative, and the present disclosure is not limited to the illustrated matters. The same reference numerals refer to the same components throughout the description.

Furthermore, in describing the present disclosure, where a detailed description of the related known technology may unnecessarily obscure the subject matter of the present disclosure, the detailed description thereof can be omitted. Where ‘comprising’, ‘including’, ‘having’, ‘consisting’, and the like are used in this disclosure, other parts can be added unless a more specific term like ‘only’ is used. Where a component is expressed in the singular, cases including the plural are included unless specific statement is described.

In interpreting the components, even if there is no separate explicit description, they should be interpreted as including a margin range.

In the case of a description of a positional relationship, for example, where the positional relationship of two parts is described as ‘on’, ‘over’, ‘above’, ‘below’, ‘beside’, ‘under’, and the like, one or more other parts can be positioned between such two parts unless a more specific term like ‘right’ or ‘directly’ is used.

In the case of a description of a temporal relationship, for example, where a temporal precedence is described as ‘after’, ‘following’, ‘before’, and the like, cases that are not continuous can be included unless a more specific term like ‘directly’ or ‘immediately’ is used.

In describing components of the present disclosure, terms such as first, second, and the like can be used. These terms are only for referring to the components separately from other components, and an essence, order, order, or number of the components is not limited by the terms.

Respective features of various embodiments of the present disclosure can be partially or wholly connected to or combined with each other and can be technically interlocked and driven variously, and respective embodiments can be independently implemented from each other or can be implemented together with an associated relationship.

Hereinafter, example embodiments of the present disclosure are described in detail with reference to the drawings. In the following embodiments, the same and like reference numerals are assigned to the same and like components, and detailed descriptions thereof may be omitted.

### First Embodiment

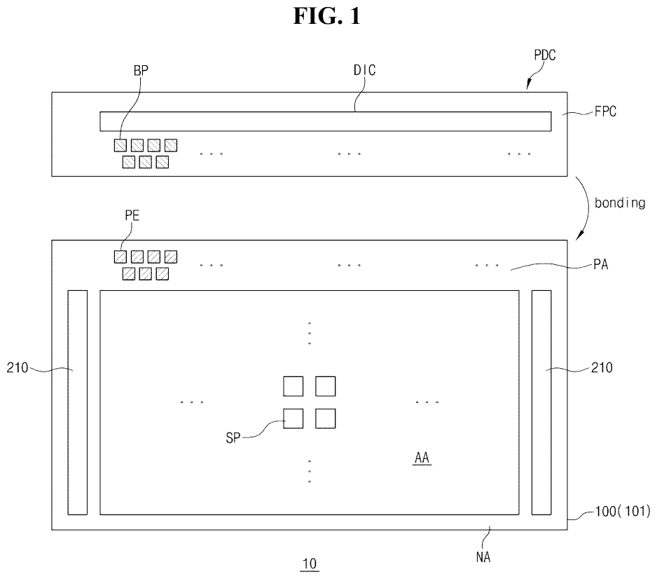

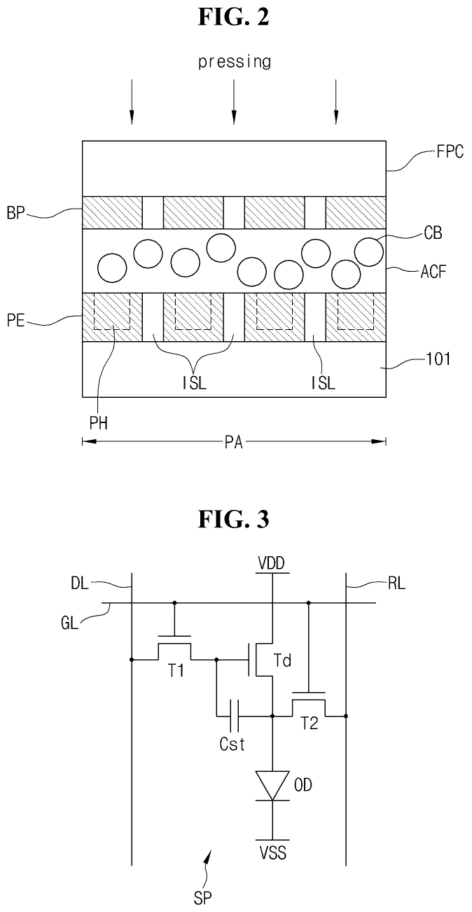

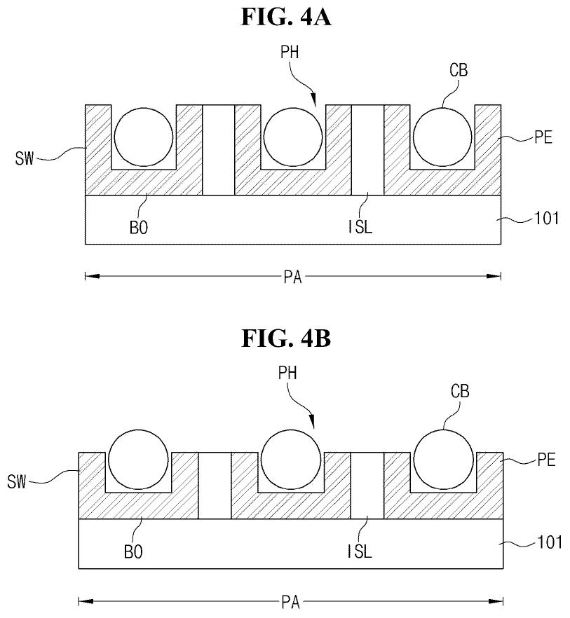

FIG. 1 is a plan view schematically illustrating a configuration of a display device according to a first example embodiment of the present disclosure. FIG. 2 is a side view schematically illustrating attachment of a display panel and a panel driving circuit in a display device according to a first example embodiment of the present disclosure. FIG. 3 is a circuit view schematically illustrating an example of a structure of a subpixel according to a first example embodiment of the present disclosure.

Prior to a detailed description, the display device 10 according to the first embodiment of the present disclosure can include any type of display device equipped with pad electrodes PE connected to a driving circuit.

In this example embodiment, for convenience of explanation, a light emitting display device (more specifically, an organic light emitting display device) equipped with light emitting diodes OD can be used as an example of the display device 10.

When the display device 10 is configured as a light emitting display device, the display device 10 can be a top emission type or bottom emission type display device.

As shown in FIGS. 1 to 3, the display device 10 of this example embodiment can include a display panel 100 for displaying an image and a driving circuit portion for driving the display panel 100.

The driving circuit portion can include a panel driving circuit PDC and a gate driving circuit 210.

In the display panel 100, a display region AA that substantially displays an image and a non-display region NA arranged around the display region AA can be defined.

The display region AA can include a plurality of subpixels SP arranged along a plurality of row lines (or horizontal lines) and a plurality of column lines (or vertical lines) on a substrate 101.

Meanwhile, a plurality of gate lines (or scan lines) GL extending along the row direction (or horizontal direction or first direction) and a plurality of data lines DL extending along the column direction (or vertical direction or second direction) can be formed on the substrate 101. Each subpixel SP can be connected to the corresponding gate line GL and data line DL.

Furthermore, a power line that transmit a high-potential driving voltage (or high-potential power voltage) VDD and a power line that transmit a low-potential driving voltage (or low-potential power voltage) VSS can be formed on the substrate 101. The high-potential driving voltage VDD and the low-potential driving voltage VSS can be applied to the subpixel SP.

The plurality of subpixels SP formed on the substrate 101 can include subpixels SP of different colors that constitute a pixel which is a unit for displaying a color image. For example, the subpixels SP constituting the pixel can include first, second and third subpixels SP that display first, second, and third colors, respectively, for example, blue, green, and red subpixels SP that display blue, green, and red, respectively. As another example, the subpixels SP constituting the pixel can further include a white subpixel that displays white.

The red, green, and blue subpixels SP can be arranged in various configurations. For example, the subpixels SP can be arranged in a stripe type, with subpixels SP of the same color arranged in the column direction and subpixels SP of different colors alternately arranged in the row direction, but not limited thereto.

Each subpixel SP can include a light emitting diode OD which is a light emitting element. Furthermore, the subpixel SP can include a pixel driving circuit that drives the light emitting diode OD. The pixel driving circuit can include a plurality of transistors including a driving transistor Td, and at least one capacitor. In this case, during an emission period, the driving transistor Td can be turned on to generate an emission current, and the emission current can be provided to the light emitting diode OD, thereby performing an emission operation.

A structure of the subpixel SP can be described with reference to FIG. 3 as an example. In FIG. 3, for convenience of explanation, the pixel driving circuit for driving the subpixel SP is illustrated as having a 3T1C structure configured with three transistors T1, T2 and Td and one capacitor Cst. Meanwhile, the structure of FIG. 3 is an example, and the pixel driving circuit can be configured with a different structure.

In the following description, the terms “source electrode” and “drain electrode” of a transistor are used to distinguish between two electrodes connected to a semiconductor layer, and can be referred to as opposite terms in some cases.

The subpixel SP can include a first transistor T1 and a second transistor T2 which are switching transistors, a driving transistor Td, a storage capacitor Cst, and a light emitting diode OD. The first transistor T1 can be a data supply transistor, and the second transistor T2 can be a driving characteristic sensing transistor.

The first transistor T1 can be connected to the corresponding gate line GL and data line DL. In this regard, a drain electrode (or source electrode) of the first transistor T1 can be connected to the data line DL, and a gate electrode of the first transistor T1 can be connected to the gate line GL.

The driving transistor Td can have a gate electrode connected to a source electrode of the first transistor T1, a drain electrode (or source electrode) to which the high-potential driving voltage VDD is applied, and a source electrode (or drain electrode) connected to an anode electrode (or first electrode) of the light emitting diode OD.

The second transistor T2 can be connected to the corresponding gate line GL and reference line RL. In this regard, a drain electrode (or source electrode) of the second transistor T2 can be connected to the reference line RL, a gate electrode of the second transistor T2 can be connected to the gate line GL, and a source electrode (or drain electrode) of the second transistor T2 can be connected to a node between the driving transistor Td and the light emitting diode OD. In other words, the source electrode of the second transistor T2 can be connected to the source electrode of the driving transistor Td and the anode electrode of the light emitting diode OD.

As such, in this embodiment, the case where the second transistor T2 and the first transistor T1 within the subpixel SP are connected to the same gate line GL and receive the same gate signal is taken as an example. As another example, the second transistor T2 can be configured to be connected to a gate line GL different from a gate line GL connected to the first transistor T1.

A cathode electrode (or second electrode) of the light emitting diode OD can receive the low-potential driving voltage VSS. The low-potential driving voltage VSS can be a voltage with a lower potential than the high potential driving voltage VDD and can include a ground voltage.

The storage capacitor Cst can be connected between the gate electrode and the source electrode of the driving transistor Td.

In the configuration as above, in operating in a display mode for displaying an image, when a gate signal of on-level is applied through the gate line GL, the first transistor T1 can be turned on, and a data signal (or data voltage) can be input to the subpixel SP, so that the data signal can be applied to the gate electrode of the driving transistor Td. At this time, the second transistor T2 can be turned on, so that a reference voltage can be applied to the source electrode of the driving transistor Td. Accordingly, the data signal and the reference voltage can be applied to both electrodes of the storage capacitor Cst, and as a result, the data signal can be stored in the storage capacitor Cst.

Then, when the gate signal of off-level is applied through the gate line GL, the first and second transistors T1 and T2 can be turned off, the driving transistor Td can be turned on, and the emission current (or driving current) corresponding to the applied data signal can flow to the light emitting diode OD through the driving transistor Td. Accordingly, during the emission period, light corresponding to the emission current can be generated and output from the light emitting diode OD.

Meanwhile, in operating in a compensation mode for compensating for the driving transistor Td, a sensing data signal can be applied to the subpixel SP, and a sensing voltage can be provided to the reference line RL via the second transistor T2. Based on the sensing voltage, a data signal for image display can be compensated, and the compensated data signal can be applied to the subpixel SP to compensate for the driving transistor Td.

The display panel 100 configured as described above can be driven using the gate driving circuit 210 and the panel driving circuit PDC constituting the driving circuit portion.

The gate driving circuit 210, which applies a gate signal to the gate line GL, can be formed, for example, in the non-display region NA of the display panel 100.

In this regard, the gate driving circuit 210 can be formed in a GIP (gate-in panel) type. The GIP type gate driving circuit 210 can be formed directly in the non-display region NA during the process of forming the pixel driving circuit.

Meanwhile, to ensure stable operation of the display panel 100, the GIP type gate driving circuit 210 can be formed on opposite sides of the display region AA, for example, in the left and right non-display regions NA.

As another example, the gate driving circuit 210 can be configured with at least one IC and mounted on the substrate 101 in a COG type or connected to the substrate 101 in a COF type.

The panel driving circuit PDC can output various driving signals that drive the display panel 100.

In this regard, for example, the panel driving circuit PDC can output the data signal. In addition, the panel driving circuit PDC can output a gate control signal that controls the operation of the gate driving circuit 210.

As such, the driving signals output from the panel driving circuit PDC can be provided to the pad electrodes PE formed on the substrate 101 of the display panel 100, and the driving signals applied to the pad electrodes PE can be transmitted through corresponding lines connected thereto.

In this regard, for example, when the data signal is applied to the corresponding pad electrode (or data pad electrode) PE, the data signal can be transmitted to the corresponding subpixel SP through the data line DL connected to the pad electrode PE. Furthermore, when the gate control signal is applied to the corresponding pad electrode (or control pad electrode) PE, the gate control signal can be transmitted to the gate driving circuit 210 through a link line connected to the pad electrode PE.

The panel driving circuit PDC can be attached (or connected or coupled) to one side of the non-display region NA of the display panel 100, for example, an upper non-display region NA.

The panel driving circuit PDC can be configured in a COF type, for example, but not limited thereto. When the panel driving circuit PDC is configured in the COF type, the panel driving circuit PDC can include, for example, a driving IC DIC and a circuit film (or flexible circuit film) FPC on which the driving IC DIC is mounted.

In this regard, the driving IC DIC can output, for example, the data signal, more specifically, the data voltage.

The circuit film FPC can be attached to the display panel 100 with the driving IC DIC mounted thereon. The circuit film FPC can have a plurality of bumps BP which are a plurality of output terminals formed on a bottom surface (or lower surface) of the circuit film FPC for outputting driving signals.

Meanwhile, a plurality of pad electrodes PE can be arranged in a pad region PA which is the non-display region NA of the display panel 100 to which the circuit film FPC is attached, and the plurality of pad electrodes PE can be respectively connected to the plurality of bumps BP arranged on the circuit film FPC.

Accordingly, the driving signal output from each bump BP of the circuit film FPC can be applied to the pad electrode PE correspondingly connected to the bump BP and transmitted to the display panel 100.

The plurality of pad electrodes PE can be arranged, for example, along an extension direction (or length direction) of the pad region PA to which the circuit film FPC is attached. In this embodiment, the pad electrodes PE can be arranged in two rows along a horizontal direction (or transverse direction) in which the pad region PA extends, but not limited thereto.

Meanwhile, when attaching the panel driving circuit PDC to the display panel 100, an anisotropic conductive film ACF can be interposed between the panel driving circuit PDC and the display panel 100 to ensure electrical connection between corresponding bumps BP and pad electrodes PE.

In this regard, as shown in FIG. 2, the anisotropic conductive film ACF interposed between the panel driving circuit PDC and the display panel 100 can include conductive balls CB dispersed therein. For example, the anisotropic conductive film ACF can be configured with the conductive balls CB dispersed within a thermoplastic or thermosetting resin.

With the anisotropic conductive film ACF interposed, a pressure can be applied toward the display panel 100, so that the bumps BP of the panel driving circuit PDC can be pressed against the pad electrodes PE of the display panel 100. Accordingly, the conductive balls CB positioned between the corresponding bump BP and pad electrode PE can be pressed and deformed by the pressure, allowing conductive layers of the conductive balls CB to contact both of the bump BP and the pad electrode PE. Consequently, the bump BP and the pad electrode PE can be electrically connected to each other by the conductive balls CB interposed therebetween.

As described above, the pad electrode PE of the display panel 100 and the bump BP of the panel driving circuit PDC can be connected to each other through the conductive ball CB of the anisotropic conductive film ACF, and accordingly, the driving signal output from the panel driving circuit PDC through the bump BP can be applied to the pad electrode PE and transmitted to the inside of the display panel 100.

Meanwhile, in this embodiment, regarding the pad electrodes PE arranged in the pad region PA of the display panel 100, a pad groove (or pad hole) PH, which is a groove (or hole) recessed in a downward direction that is a direction toward the substrate 101, can be formed within the pad electrode PE. In other words, the pad electrode PE can be configured in a bowl shape with the pad groove PH formed therein.

As such, when the pad groove PH is formed in the pad electrode PE, an inner surface (or internal surface) of the pad electrode PE surrounding and defining the pad groove PH can also function as a connection surface (or contact surface), and as a result, the connection surface of the pad electrode PE can be increased.

In other words, by forming the pad electrode PE with the pad groove PH therein, the inner surface extending in a depth direction of the pad groove PH can be added as a connection surface, thereby increasing the connection surface of the pad electrode PE.

Accordingly, a size (or width) of each pad electrode PE i.e., a planar area of each pad electrode PE can be reduced, which in turn can reduce a pitch which is a distance between the pad electrodes PE arranged.

Therefore, even if a resolution of the display device 10 increases, it is possible to arrange the pad electrodes PE with a narrow pitch.

A structure of the pad electrode PE with the pad groove PH formed therein can be described in more detail below.

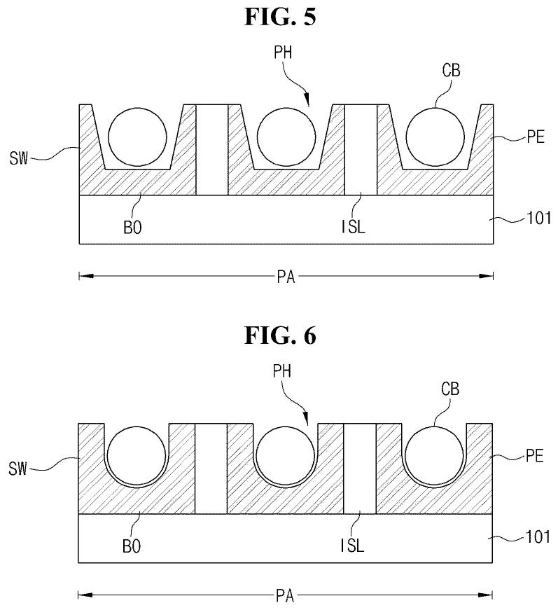

FIGS. 4A to 6 are cross-sectional views illustrating various examples of a structure of a pad groove formed in a pad electrode according to a first example embodiment of the present disclosure. For convenience of explanation, the structures of the pad grooves illustrated in FIGS. 4A and 4B, 5, and 6 are referred to as the structures of first to third examples, respectively.

As shown in FIGS. 4A to 6, the pad electrodes PE can be arranged in the pad region PA on the substrate 101 of the display panel 100.

The substrate 101 can be an insulating substrate, such as a glass substrate or a plastic substrate. As another example, the substrate 101 can be a silicon substrate (or silicon wafer) formed of crystalline silicon (e.g., single crystal silicon) that functions as a semiconductor, and in this case, there is an advantage in that it can effectively implement a small-sized display device with high resolution. In this embodiment, for convenience of explanation, an insulating substrate is used as an example.

The pad electrode PE can be formed of a metal with conductive property, such as Mo, Al, Cu, or Ti, but not limited thereto.

Meanwhile, in the pad region PA, a unit region where each pad electrode PE is formed can be referred to as a unit pad region. Each pad electrode PE can have the pad groove PH recessed downward therein.

In this case, the pad electrode PE can have an inner surface defining the pad groove PH. In this regard, the pad electrode PE can have an inner side surface surrounding the pad groove PH along a periphery of the pad groove PH, and a bottom surface below the pad groove PH. In other words, the pad electrode PE can include a sidewall portion SW surrounding the pad groove PH along a periphery of the pad groove PH and a bottom portion BO positioned below the pad groove PH.

In addition, an insulating layer ISL can be interposed between adjacent pad electrodes PE. In other words, the adjacent pad electrodes PE can be physically separated (or distinguished) by the insulating layer ISL.

As such, the insulating layer ISL can function as a partition wall separating the pad electrodes PE. For example, the insulating layer ISL can be configured in a form such that openings are formed inside the insulating layer ISL and each pad electrode PE is inserted into the corresponding opening.

The insulating layer ISL can be formed of an inorganic insulating material and/or an organic insulating material.

Here, a size (or width or planar area) of the pad groove PH of the pad electrode PE can be formed to be equal to or larger than a size (or diameter or planar area) of the conductive ball CB. When the bump BP of the panel driving circuit PDC is pressed against the pad electrode PE of the display panel 100 with a certain pressure, the pad electrode PE can be deformed while being pressed, so that the conductive ball CB can come into contact with the bump BP and the pad electrode PE.

As another example, as shown in FIG. 4B, a depth of the pad groove PH or a height of the sidewall portion SW of the pad groove PH can be smaller than a size (or diameter) of the conductive ball CB. Accordingly, a part of an upper portion of the conductive ball CB can protrude from an end (or top end) of the pad groove PH, and when the bump BP of the panel driving circuit PDC is pressed against the pad electrode PE of the display panel 100, the conductive ball CB can be pressed by a pressure and can securely contact the bump BP and the pad electrode PE. The embodiment of the present disclosure is not limited thereto, and the pad groove PH and the conductive ball CB can be formed in various sizes.

In this embodiment, for convenience of explanation, the case in which the pad groove PH is formed such that the conductive ball CB is positioned within the pad groove PH is illustrated as an example.

The pad groove PH of the pad electrode PE can be formed in various shapes.

In this regard, in the first example of FIGS. 4A and 4B, the pad groove PH can have a substantially rectangular shape when viewed in cross-section. In other words, the pad groove PH can be formed in a rectangular shape with a constant width in the depth direction of the pad groove PH.

Meanwhile, in the second example of FIG. 5, the pad groove PH can have a roughly trapezoidal shape with a narrower width at a bottom when viewed in cross-section. In other words, in the depth direction of the pad groove PH, the pad groove PH can be formed in a trapezoidal shape with a narrower width as it goes downward.

Meanwhile, in the third example of FIG. 6, the pad groove PH can be formed such that a bottom surface (or an upper surface of the bottom portion BO) has a rounded shape when viewed in cross-section. In other words, in the depth direction of the pad groove PH, the pad groove PH can be formed to have a rectangular upper portion with a constant width as it goes downward in the depth direction, and a rounded lower portion with a narrower width as it goes downward in the depth direction.

As described above, in this example embodiment, the pad electrode PE can be formed with the pad groove PH recessed therein.

Accordingly, the inner surface extending in the depth direction of the pad groove PH can be added as a connection surface in the pad electrode PE, thereby increasing the connection surface.

Accordingly, the area occupied by the pad electrodes PE can be reduced, and thus the pitch of the pad electrodes PE can be reduced.

Therefore, even if a resolution of the display device 10 increases, the pad electrodes PE can be arranged with a narrow pitch, so that the pad electrodes PE can be effectively formed even at high resolution.

### Second Embodiment

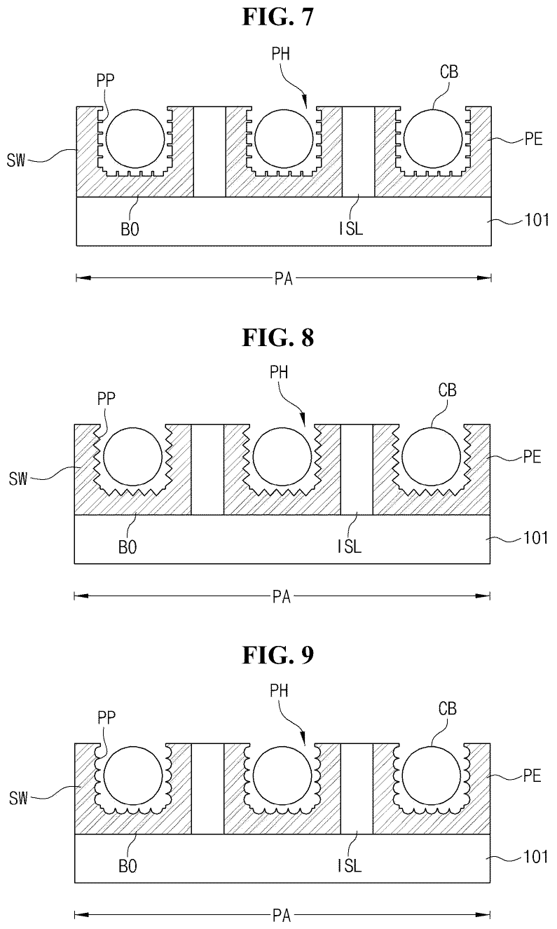

FIGS. 7 to 9 are cross-sectional views illustrating various examples of a structure of a pad groove formed in a pad electrode of a display device according to a second example embodiment of the present disclosure. For convenience of explanation, the structures of the pad grooves illustrated in FIGS. 7 to 9 are referred to as the structures of first to third examples, respectively.

In the following description, detailed explanations of components identical to or similar to those of the first example embodiment can be omitted.

Similar to the first example embodiment, the pad electrode PE of the display device according to the second example embodiment of the present disclosure can have the pad groove PH formed therein to increase the connection surface. This can allow the size of the pad electrode PE to be reduced, thereby reducing the pitch of the pad electrode PE.

Meanwhile, the pad groove PH of the pad electrode PE of the second example embodiment can be formed with an uneven structure.

In this regard, as shown in FIGS. 7 to 9, the inner side surface of the pad electrode PE surrounding the pad groove PH and the bottom surface of the pad electrode PE below the pad groove PH can be formed to have the uneven shape such that protrusions PP protruding inwardly toward the pad groove PH and recess portions recessed outwardly from the pad groove PH are repeatedly arranged.

In other words, in the pad electrode PE, the protrusions PP can be positioned at regular intervals on the inner surface of the pad electrode PE and protrude toward the pad groove PH, and recessed spaces can be defined between adjacent protrusions PP.

As such, when the pad groove PH is formed with the uneven structure, the area of the inner surface of the pad electrode PE can be further increased, thereby further increasing the connection surface of the pad electrode PE.

Meanwhile, the insulating layer ISL can be interposed between adjacent pad electrodes PE, so that the adjacent pad electrodes PE can be physically separated by the insulating layer ISL.

The uneven structure of the pad groove PH can be formed in various shapes.

In this regard, in the first example of FIG. 7, the protrusions PP of the pad electrode PE can be arranged at a regular distance apart. For example, the protrusions PP can be formed to have a constant width overall, and the recessed space between adjacent protrusions PP can be formed into a rectangular shape of a substantially constant width. In other words, when one end of the protrusion PP facing the pad groove PH is referred to as a first end and the other end of the protrusion PP opposite to the first end is referred to as a second end, the first ends of adjacent protrusions PP can be spaced apart from each other by a constant distance, and the second ends of adjacent protrusions PP can also be spaced apart from each other by a constant distance.

Meanwhile, in the second example of FIG. 8, the protrusion PP of the pad electrode PE can be formed to have a shape increases in width as it goes outward from the pad groove PH. In addition, the second ends of the adjacent protrusions PP can be formed to contact each other. In the second example, the separate region between the adjacent protrusions PP can be formed to have an approximately triangular shape.

Meanwhile, in the third example of FIG. 9, similar to the second example of FIG. 8, the protrusion PP of the pad electrode PE can be formed to have a shape that increases in width as it goes outward from the pad groove PH. In addition, the second ends of the adjacent protrusions PP can be formed to contact each other. In the third example, the separate region between adjacent protrusions PP can be formed to have an approximately rounded shape.

### Third Embodiment

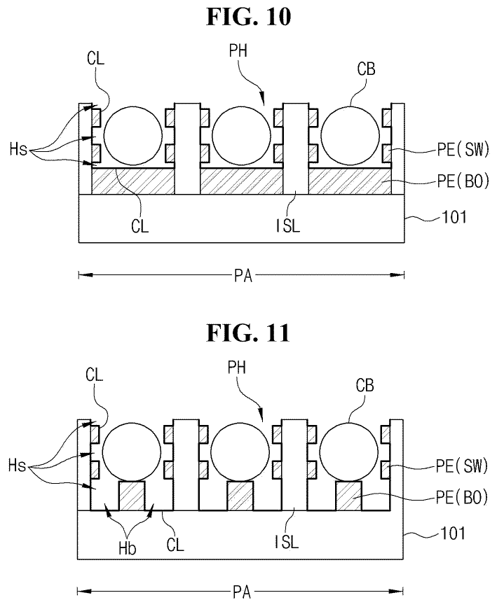

FIGS. 10 and 11 are cross-sectional views illustrating various examples of a structure of a pad groove formed in a pad electrode of a display device according to a third example embodiment of the present disclosure. For convenience of explanation, the structures of the pad grooves illustrated in FIGS. 10 and 11 are referred to as the structures of first and second examples, respectively.

In the following description, detailed explanations of components identical to or similar to those of the first and/or second example embodiments can be omitted.

Similar to the first and/or second example embodiments, the pad electrode PE of the display device according to the third example embodiment of the present disclosure can have the pad groove PH formed therein to increase the connection surface. Accordingly, the size of the pad electrode PE can be reduced, thereby reducing the pitch of the pad electrode PE.

Furthermore, similar to the second example embodiment, the pad groove PH of the pad electrode PE of the third example embodiment can be formed with the uneven structure, further increasing the connection surface.

Meanwhile, in the third example embodiment, the pad groove PH can be defined by being surrounded by the inner surface of the pad electrode PE and the inner surface of the insulating layer ISL.

Furthermore, a conductive thin film CL can be deposited along the inner surface of the pad electrode PE and the inner surface of the insulating layer ISL defining the pad groove PH, such that the conductive thin film CL can substantially define the pad groove PH. Here, the conductive thin film CL can be formed of a metal with conductive property, such as, but not limited to, Mo, Al, Cu, or Ti.

The conductive thin film CL comes into contact with the pad electrode PE, so that a combination of the conductive thin film CL and the pad electrode PE can serve as a unit pad electrode including the pad groove PH.

In this regard, as shown in the first example of FIG. 10, the pad electrode PE can be formed, for example, such that the sidewall portion SW has a first groove (or first hole) Hs. In this regard, at least one first groove Hs can be formed in the sidewall portion SW, and the insulating layer ISL that contacts the outside of the sidewall portion SW can be configured to be exposed to the pad groove PH through the first groove Hs. In this case, the sidewall portion SW can be configured to include patterned portions spaced vertically with the first groove Hs interposed therebetween.

Meanwhile, the bottom portion BO of the pad electrode PE may not have a groove formed therein, but can be formed continuously throughout.

In this case, since the side surface of the pad groove PH can be substantially defined by the inner surface of the pad electrode PE and the inner surface of the insulating layer ISL (i.e., the side surface of the insulating layer ISL exposed by the first groove Hs), the side surface of the pad groove PH can be configured in an uneven shape.

In addition, since the bottom surface of the pad groove PH can be substantially defined by the bottom surface of the pad electrode PE, the bottom surface of the pad groove PH can be configured in a flat shape.

In this case, the conductive thin film CL can cover the inner surface of the pad electrode PE and the inner surface of the insulating layer ISL defining the pad groove PH.

The conductive thin film CL can be formed along the side and bottom surfaces of the pad groove PH in a shape substantially identical to the side and bottom surfaces of the pad groove PH. Accordingly, the conductive thin film CL can substantially enclose and define the pad groove PH.

The conductive thin film CL can be formed to have a thickness smaller than the pad electrode PE.

As shown in the second example of FIG. 11, similar to the first example of FIG. 10, the pad electrode PE can be formed, for example, such that the sidewall portion SW has the first groove Hs. Alternatively, the sidewall portion SW can be formed without a groove.

In addition, the bottom portion BO of the pad electrode PE can be formed, for example, to have a second groove (or second hole) Hb, similar to the sidewall portion SW. In this regard, at least one second groove Hb can be formed in the bottom portion BO, and a portion of the substrate 101 below the bottom portion BO can be configured to be exposed to the pad groove PH through the second groove Hb. In this case, the bottom portion BO can be configured to include a patterned portion arranged between the second grooves Hb.

In this case, since the side surface of the pad groove PH can be substantially defined by the inner surface of the pad electrode PE and the inner surface of the insulating layer ISL, the side surface of the pad groove PH can be configured in an uneven shape.

Furthermore, since the bottom surface of the pad groove PH can be substantially defined by the bottom surface of the pad electrode PE and the bottom surface of the substrate 101 (i.e., the surface of the substrate 101 exposed by the second groove Hb), the bottom surface of the pad groove PH can be configured in an uneven shape.

In this case, the conductive thin film CL can cover the inner surface of the pad electrode PE, the inner surface of the insulating layer ISL and the surface of the substrate 101 defining the pad groove PH.

The conductive thin film CL can be formed along the side and bottom surfaces of the pad groove PH in a shape substantially identical to the side and bottom surfaces of the pad groove PH. Accordingly, the conductive thin film CL can substantially enclose and define the pad groove PH.

The conductive thin film CL can be formed to have a thickness smaller than the pad electrode PE.

As described above, in this embodiment, the combination of the pad electrode PE and the conductive thin film CL that contacts the inner surface of the pad electrode PE and is formed along the pad groove PH can substantially function as a unit pad electrode. Accordingly, the pad electrode PE can serve as a first electrode, the conductive thin film CL which the conductive ball CB directly contacts can serve as a second electrode, and the combination of the first and second electrodes can be considered to constitute a pad electrode.

### Fourth Embodiment

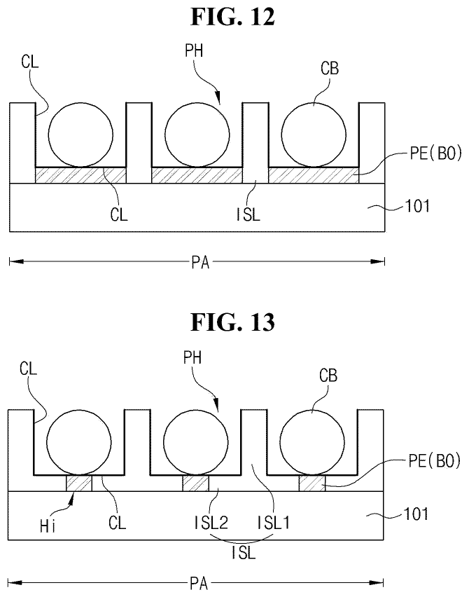

FIGS. 12 and 13 are cross-sectional views illustrating various examples of a structure of a pad groove formed in a pad electrode of a display device according to a fourth example embodiment of the present disclosure. For convenience of explanation, the structures of the pad grooves illustrated in FIGS. 12 and 13 are referred to as the structures of first and second examples, respectively.

In the following description, detailed explanations of components identical to or similar to those of the first, second, and/or third example embodiments can be omitted.

In the display device according to the fourth example embodiment of the present disclosure, the pad groove PH can be defined by being surrounded by the inner surface of the pad electrode PE and the inner surface of the insulating layer ISL, and the pad groove PH can be formed in a shape similar to that of the first example embodiment.

In addition, similar to the third example embodiment, the conductive thin film CL can be deposited along the side and bottom surfaces of the pad groove PH, so that the conductive thin film CL can substantially define the pad groove PH.

As such, in this example embodiment, the pad groove PH can be formed in the combination of the pad electrode PE and the conductive thin film CL constituting a unit pad electrode, thereby increasing the connection surface. Accordingly, the size of the pad electrode PE can be reduced, thereby reducing the pitch of the pad electrode PE.

In this regard, as shown in the first example of FIG. 12, the pad electrode PE can be configured, for example, with the bottom portion BO without a sidewall portion. In other words, the pad electrode PE can be formed as a conductive film laminated to a certain thickness on the substrate 101.

In this case, the pad groove PH can be defined in the combination of the pad electrode PE formed as the bottom portion BO and the insulating layer ISL which is arranged along a periphery of the pad electrode PE and functions as a partition wall.

In this case, the pad groove PH can be surrounded by the insulating layer ISL, so that the side surface of the pad groove PH can be defined by the inner side surface of the insulating layer ISL.

Furthermore, the pad electrode PE can be disposed below the pad groove PH, so that the bottom surface of the pad groove PH can be defined by an upper surface of the pad electrode PE.

In this case, the conductive thin film CL can cover the inner surfaces of the pad electrode PE and the insulating layer ISL defining the pad groove PH.

The conductive thin film CL can be formed along the side and bottom surfaces of the pad groove PH in a shape substantially identical to the side and bottom surfaces of the pad groove PH. Accordingly, the conductive thin film CL can substantially enclose and define the pad groove PH.

The conductive thin film CL can be formed to have a thickness smaller than the pad electrode PE.

As shown in the second example of FIG. 13, the pad electrode PE can be configured, for example, with the bottom portion BO without a sidewall portion. The pad electrode PE of the second example can be formed with a narrower width than the pad electrode PE of the first example of FIG. 12.

In this case, the pad groove PH can be defined in the combination of the pad electrode PE configured as the narrow bottom portion BO and the insulating layer ISL which is arranged along a periphery of the pad electrode PE.

In this case, the insulating layer ISL can be configured with, for example, a first portion ISL1 serving as a partition wall portion and a second portion ISL2 serving as a bottom portion.

The first portion ISL1 can substantially correspond to the insulating layer ISL of the first example of FIG. 12, and can surround the pad groove PH. Thus, the side surface of the pad groove PH can be defined by the inner side surface of the first portion ISL1 of the insulating layer ISL.

The second portion ISL2 along with the pad electrode PE formed as the narrow bottom portion BO can be positioned, for example, below the pad groove PH. As such, the bottom surface of the pad groove PH can be defined by the upper surface of the second portion ISL2 of the insulating layer ISL and the upper surface of the pad electrode PE.

Meanwhile, the second portion ISL2 of the insulating layer ISL can include, for example, a groove (or third groove) Hi in which the pad electrode PE is positioned (or inserted). Accordingly, the combination of the second portion ISL2 of the insulating layer ISL and the pad electrode PE positioned in the groove Hi can be positioned below the pad groove PH.

In this case, the conductive thin film CL can cover the inner surfaces of the pad electrode PE and the insulating layer ISL defining the pad groove PH.

The conductive thin film CL can be formed along the side and bottom surfaces of the pad groove PH in a shape substantially identical to the side and bottom surfaces of the pad groove PH. Accordingly, the conductive thin film CL can substantially enclose and define the pad groove PH.

This conductive thin film CL can be formed to have a thickness smaller than the pad electrode PE.

As described above, in this embodiment, the combination of the conductive thin film CL, which contacts the inner surfaces of the pad electrode PE and the insulating layer ISL and is formed along the pad groove PH, and the pad electrode PE can substantially function as a unit pad electrode. Accordingly, the pad electrode PE can serve as a first electrode, the conductive thin film CL which the conductive ball CB directly contacts can serve as a second electrode. and the combination of the first and second electrodes can be considered to constitute a pad electrode.

As described above, in this embodiment, the pad electrode PE can be formed with a sidewall portion omitted. Accordingly, the size of the pad electrode PE can be further reduced, and thus the pitch of the pad electrode PE can be further reduced.

### Fifth Embodiment

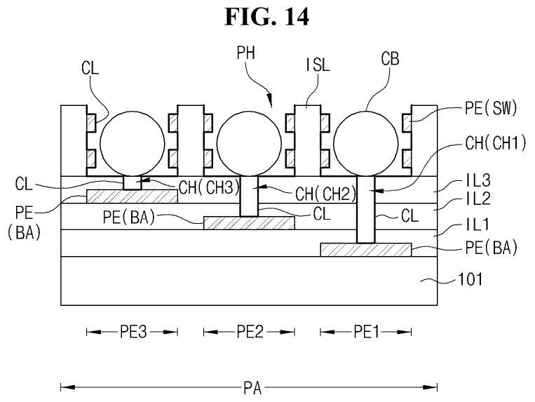

FIG. 14 is a cross-sectional view illustrating an example of a structure of a pad groove formed in a pad electrode of a display device according to a fifth example embodiment of the present disclosure.

In the following description, detailed explanations of components identical or similar to those of the first, second, third, and/or fourth example embodiments can be omitted.

In the display device according to the fifth example embodiment of the present disclosure, the pad groove PH can be formed in a unit pad region where a pad electrode PE is formed, similar to the first to fourth example embodiments. For example, the pad groove PH can be configured to be defined by being surrounded by the sidewall portion SW of the pad electrode PE, the insulating layer ISL disposed on the outside of the sidewall portion SW, and an upper surface of an insulating layer IL3 disposed below the sidewall SW. Similar to the pad groove PH of the first example of the third example embodiment (see FIG. 10), the side surface of the pad groove PH can be configured in an uneven shape.

Similar to the third and fourth example embodiments, the conductive thin film CL can be deposited along the side and bottom surfaces of the pad groove PH, so that the conductive thin film CL can substantially define the pad groove PH.

Furthermore, unlike the previously described example embodiments, the pad electrode PE of this embodiment can be configured to include a base portion BA covered by an insulating layer formed below the pad groove PH without a bottom portion (BO of FIGS. 4 to 13) directly below the pad groove PH. The base portion BA can contact the conductive thin film CL through a contact hole CH formed in the insulating layer covering the base portion BA.

A structure of the pad groove PH and the pad electrode PE configured in this manner can be described below.

In this example embodiment, the pad electrodes PE arranged in the pad region PA can include pad electrodes PE having base portions BA with different heights. For convenience of explanation, the case where the pad electrodes PE arranged in the pad region PA include three pad electrodes, namely, a first pad electrode PE1 to a third pad electrode PE3 having respective base portions BA that are different in height. The first pad electrodes PE1 to the third pad electrodes PE3 can be arranged adjacent to each other, and can be arranged alternately and repeatedly in the pad region PA.

The first pad electrode PE1 can have the base portion BA formed on the substrate 101. A first interlayered insulating layer (or first insulating layer) IL1 can be formed on the base portion BA of the first pad electrode PE1. The base portion BA of the second pad electrode PE2 can be formed on the first interlayered insulating layer IL1. A second interlayered insulating layer (or second insulating layer) IL2 can be formed on the base portion BA of the second pad electrode PE2. The base portion BA of the third pad electrode PE3 can be formed on the second interlayered insulating layer IL2. A third interlayered insulating layer (or third insulating layer) IL3 can be formed on the base portion BA of the third pad electrode PE3.

As described above, the base portions BA of adjacent pad electrodes PE can be formed at different layers with an insulating layer interposed therebetween. As such, the base portions BA of the adjacent pad electrodes PE can be separated by the insulating layer, thereby preventing or suppressing a short circuit between them. In this case, the pad electrodes PE can be arranged closer, thereby substantially reducing the pitch of the pad electrodes PE.

Meanwhile, a first contact hole CH1, which is a contact hole CH exposing the base portion BA of the first pad electrode PE1, can be formed in the first to third interlayered insulating layers IL1 to IL3 disposed on the base portion BA of the first pad electrode PE1. A second contact hole CH2, which is a contact hole CH exposing the base portion BA of the second pad electrode PE2, can be formed in the second and third interlayered insulating layers IL2 and IL3 disposed on the base portion BA of the second pad electrode PE2. A third contact hole CH3, which is a contact hole CH exposing the base portion BA of the third pad electrode PE3, can be formed in the third interlayered insulating layer IL3 disposed on the base portion BA of the third pad electrode PE3.

As such, the contact hole CH exposing the base BA of each pad electrode PE can be formed on the base BA of each pad electrode PE.

In the contact hole CH, the conductive thin film CL formed along the inner surface of the pad groove PH corresponding to each pad electrode PE can be formed. For example, the conductive thin film CL can be formed along an inner surface (i.e., a side surface and a bottom surface) of the corresponding contact hole CH. As such, the conductive thin film CL formed in the pad groove PH can extend along the contact hole CH and be connected to the base portion BA of each pad electrode PE.

In this regard, the conductive thin film CL formed in the pad groove PH corresponding to the first pad electrode PE1 can extend along the inner surface of the first contact hole CH1 and contact the base portion BA of the first pad electrode PE1. The conductive thin film CL formed in the pad groove PH corresponding to the second pad electrode PE2 can extend along the inner surface of the second contact hole CH2 and contact the base portion BA of the second pad electrode PE2. The conductive thin film CL formed in the pad groove PH corresponding to the third pad electrode PE3 can extend along the inner surface of the third contact hole CH3 and contact the base portion BA of the third pad electrode PE3.

As described above, in this example embodiment, the combination of the conductive thin film CL, which contacts the inner surfaces of the pad electrode PE and the insulating layers ISL and IL3 and is formed along the pad groove PH, and the pad electrode PE can substantially function as a unit pad electrode. Accordingly, the pad electrode PE can serve as a first electrode, the conductive thin film CL which the conductive ball CB directly contacts can serve as a second electrode, and the combination of the first and second electrodes can be considered to constitute a pad electrode.

As described above, according to the example embodiments of the present disclosure, the pad groove, which is defined by being surrounded by at least a portion of the pad electrode, can be formed in a unit region where the pad electrode is disposed. In some cases, the pad groove can have an uneven structure, and/or the conductive thin film can be formed along the pad groove.

By forming the pad groove corresponding to the pad electrode as above, the connection surface of the pad electrode can be increased. Therefore, the region occupied by the pad electrode can be reduced, thereby reducing the pitch of the pad electrode.

In this case, even if the resolution of the display device increases, the pad electrodes can be arranged with a narrow pitch, so that the pad electrodes can effectively formed even at high resolution.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display device, comprising:
a display panel including a plurality of pad electrodes arranged on a pad region of a substrate; and
a panel driving circuit attached to the pad region through an anisotropic conductive film containing conductive balls and including bumps respectively connected to the plurality of pad electrodes through the conductive balls,
wherein a pad groove defined by at least a portion of a pad electrode, among the plurality of pad electrodes, is formed in a unit region where the pad electrode is disposed.

2. The display device of claim 1, further comprising an insulating layer interposed between adjacent pad electrodes among the plurality of pad electrodes.

3. The display device of claim 1, wherein the pad groove has a shape in which a width of the pad groove is constant along a direction toward the substrate, or a shape in which a width of the pad groove becomes narrower, at least at a lower portion of the pad groove, along a direction toward the substrate.

4. The display device of claim 1, wherein at least one of a side surface and a bottom surface of the pad groove has an uneven shape.

5. The display device of claim 4, wherein the pad electrode includes a protrusion that forms the uneven shape of the pad groove, and
wherein the protrusion has a shape in which a width of the protrusion is constant or increases from a first end facing the pad groove to a second end opposite to the first end.

6. The display device of claim 1, wherein the pad electrode includes a sidewall portion surrounding the pad groove and a bottom portion below the pad groove.

7. The display device of claim 6, wherein a height of the sidewall portion is smaller than a diameter of the conductive ball.

8. The display device of claim 2, further comprising a conductive thin film formed along side and bottom surfaces of the pad groove and contacting the pad electrode.

9. The display device of claim 8, wherein the pad electrode includes a sidewall portion surrounding the pad groove and a bottom portion below the pad groove,
wherein at least one of the sidewall portion and the bottom portion has a groove, and
wherein the pad groove has an uneven shape by the groove.

10. The display device of claim 8, wherein the pad electrode includes a bottom portion below the pad groove, and
wherein the conductive thin film is formed along an inner surface of the insulating layer and an upper surface of the bottom portion.

11. The display device of claim 10, wherein the insulating layer includes a bottom portion located below the pad groove, and
wherein the bottom portion of the insulating layer includes a groove in which the bottom portion of the pad electrode is disposed.

12. The display device of claim 8, further comprising an interlayered insulating layer positioned between the substrate and the pad groove, and having a contact hole formed therein,
wherein the pad electrode includes:
a sidewall portion surrounding the pad groove; and
a base portion which is positioned between the interlayered insulating layer and the substrate, and contacts the conductive thin film extending along the contact hole.

13. The display device of claim 12, wherein the plurality of pad electrodes arranged in the pad region include a first pad electrode and a second pad electrode,
wherein a first interlayered insulating layer is formed on the base portion of the first pad electrode,
wherein the base portion of the second pad electrode is formed on the first interlayered insulating layer,
wherein a second interlayered insulating layer is formed on the base portion of the second pad electrode,
wherein the base portion of the first pad electrode contacts the conductive thin film extending along a first contact hole formed in the first and second interlayered insulating layers, and
wherein the base portion of the second pad electrode contacts the conductive thin film extending along a second contact hole formed in the second interlayered insulating layer.

14. The display device of claim 13, wherein the plurality of pad electrodes arranged in the pad region further include a third pad electrode,
wherein the base portion of the third pad electrode is formed on the second interlayered insulating layer,
wherein a third interlayered insulating layer is formed on the base portion of the third pad electrode,
wherein the base portion of the first pad electrode contacts the conductive thin film extending along the first contact hole formed in the first to third interlayered insulating layers,
wherein the base portion of the second pad electrode contacts the conductive thin film extending along the second contact hole formed in the second and third interlayered insulating layers, and
wherein the base portion of the third pad electrode contacts the conductive thin film extending along a third contact hole formed in the third interlayered insulating layer.

15. The display device of claim 8, wherein the conductive thin film has a thickness smaller than the pad electrode.

16. The display device of claim 9, wherein the sidewall portion of the pad electrode has a first groove,
wherein the bottom portion of the pad electrode has a second groove,
wherein the insulating layer is exposed to the pad groove through the first groove, and
wherein the substrate is exposed to the pad groove through the second groove.

17. A display device, comprising:
a display panel including a display region and a non-display region arranged around the display region; and
a driving circuit portion for driving the display panel,
wherein the non-display region includes a pad region, and a plurality of pad electrodes is arranged on a substrate in the pad region, and
wherein a pad groove is formed in at least one of the plurality of pad electrodes.

18. The display device of claim 17, further comprising a conductive thin film formed along side and bottom surfaces of the pad groove and contacting the pad electrode,
wherein an insulating layer is interposed between adjacent pad electrodes, and
wherein the pad electrode includes a bottom portion below the pad groove.

19. The display device of claim 18, wherein the conductive thin film covers a surface of the substrate and the bottom portion of the pad electrode.

20. The display device of claim 18, wherein the pad electrode further includes a sidewall portion surrounding the pad groove, and
wherein the conductive thin film covers the sidewall portion of the pad electrode and an inner surface of the insulating layer.
